(19) United States
(12) Patent Application Publication
(10) Pub. No.: US 2026/0026087 A1
(43) Pub. Date: Jan. 22, 2026

(54) AREA SCALING USING AN EXTENDED FULL CUT WITH A DIELECTRIC CAP

(71) Applicant: QUALCOMM Incorporated, San Diego, CA (US)

(72) Inventors: Shreesh NARASIMHA, Charlotte, NC (US); Yan SUN, San Diego, CA (US)

(21) Appl. No.: 18/774,076

(22) Filed: Jul. 16, 2024

(51) Int. Cl. H01L 27/088; H01L 21/8234; H01L 23/522; H01L 29/06; H01L 29/423; H01L 29/775; H01L 29/78; H01L 29/786

(52) U.S. Cl. CPC H10D 84/83; H01L 23/5226; H10D 84/0151; H10D 84/038; H10D 30/43; H10D 30/62; H10D 30/6735; H10D 30/6757; H10D 62/121

(57) ABSTRACT

A chip includes one or more first channels extending in a first direction, a first epitaxial (epi) layer coupled to the one or more first channels, one or more second channels extending in the first direction, a second epi layer coupled to the one or more second channels, and a first gate extending in a second direction perpendicular to the first direction, wherein the one or more first channels and the one or more second channels pass through the first gate. The chip also includes a first dielectric wall extending in the first direction, wherein the first dielectric wall is disposed between the first epi layer and the second epi layer, and a dielectric cap disposed on the first gate.

### BACKGROUND

### Field

Aspects of the present disclosure relate generally to chip layout, and more particularly, to area scaling using an extended full cut with a dielectric cap.

### Background

A chip includes many transistors for performing various functions on the chip. The transistors may be implemented using gate-all-around field effect transistors (GAAFETs), fin field effect transistors (FinFETs), and/or other types of transistors. With advances in semiconductor technology, there is a continuous demand to scale down the dimensions of the transistors and the spacing between the transistors to fit a larger number of transistors on the chip.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes one or more first channels extending in a first direction, a first epitaxial (epi) layer coupled to the one or more first channels, one or more second channels extending in the first direction, a second epi layer coupled to the one or more second channels, and a first gate extending in a second direction perpendicular to the first direction, wherein the one or more first channels and the one or more second channels pass through the first gate. The chip also includes a first dielectric wall extending in the first direction, wherein the first dielectric wall is disposed between the first epi layer and the second epi layer, and a dielectric cap disposed on the first gate.

A second aspect relates to a method of chip fabrication. A chip includes a gate, a dielectric cap disposed on the gate, one or more first channels passing through the gate, one or more second channels passing through the gate, a first epitaxial (epi) layer coupled to the one or more first channels, and a second epi layer coupled to the one or more second channels. The method includes etching the chip within an area extending in a first direction, wherein the area overlaps a portion of the dielectric cap, a portion of the first epi layer, and a portion of the second epi layer, and wherein the etching forms a trench extending in the first direction between first epi layer and the second epi layer, and the dielectric cap protects the gate from the etching. The method also includes filling the trench with a dielectric material to form a dielectric wall.

### BRIEF DESCRIPTION OF THE DRAWINGS

FIG. 1A shows a side view of an example of a chip including a transistor and multiple topside layers according to certain aspects of the present disclosure.

FIG. 1B shows a perspective view of the transistor implemented with a gate-all-around FET according to certain aspects of the present disclosure.

FIG. 1C shows a perspective view of the transistor implemented with a finFET according to certain aspects of the present disclosure.

FIG. 1D shows a side view of the chip of FIG. 1A further including multiple backside layers according to certain aspects of the present disclosure.

FIG. 1E shows a side view of the chip of FIG. 1D further including a via disposed between a backside contact and a backside metal layer according to certain aspects of the present disclosure.

FIG. 1F shows a side view of a dielectric cap formed on a gate of the transistor according to certain aspects of the present disclosure.

FIG. 2A shows a top view of an example of a cell including a first transistor and a second transistor according to certain aspects of the present disclosure.

FIG. 2B shows a top view of an example of dielectric caps formed on gates according to certain aspects of the present disclosure.

FIG. 2C shows a first cross-sectional view of the cell according to certain aspects of the present disclosure.

FIG. 2D shows a second cross-sectional view of the cell according to certain aspects of the present disclosure.

FIG. 3A shows a top view of a dielectric wall that extends between epi layers according to certain aspects of the present disclosure.

FIG. 3B shows a cross-sectional view of the dielectric wall and the epi layers according to certain aspects of the present disclosure.

FIG. 3C shows a cross-sectional view of gates and a dielectric cap on the gates according to certain aspects of the present disclosure.

FIG. 4A shows an example of an etching process forming a trench between epi layers according to certain aspects of the present disclosure.

FIG. 4B shows an example of the etching process forming a divot in the dielectric cap according to certain aspects of the present disclosure.

FIG. 5A shows a top view of an example of signal routing for a cell according to certain aspects of the present disclosure.

FIG. 5B shows a cross-sectional view of the cell taken along a first cross-section line in FIG. 5A according to certain aspects of the present disclosure.

FIG. 5C shows a cross-sectional view of the cell taken along a second cross-section line in FIG. 5A according to certain aspects of the present disclosure.

FIG. 5D shows a cross-sectional view of the cell taken along a third cross-section line in FIG. 5A according to certain aspects of the present disclosure.

FIG. 6 is a flowchart illustrating method of chip fabrication according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

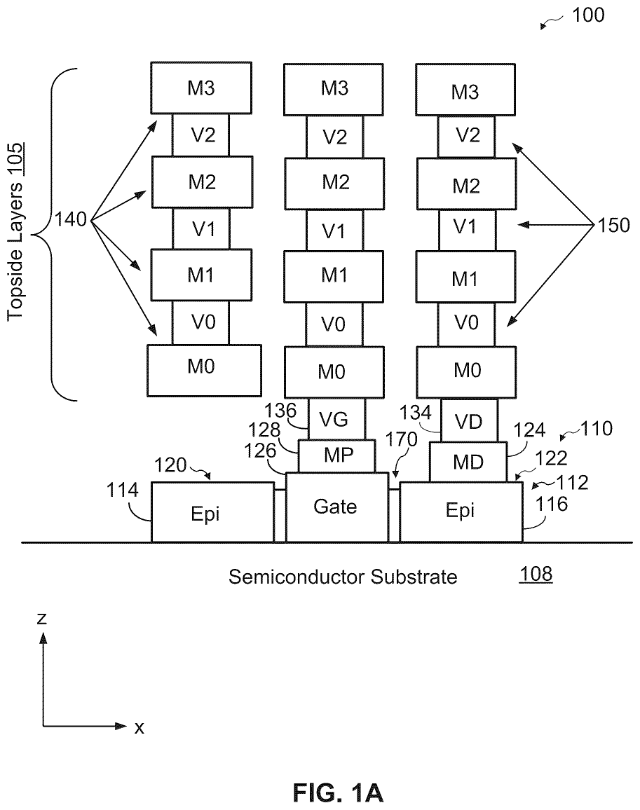

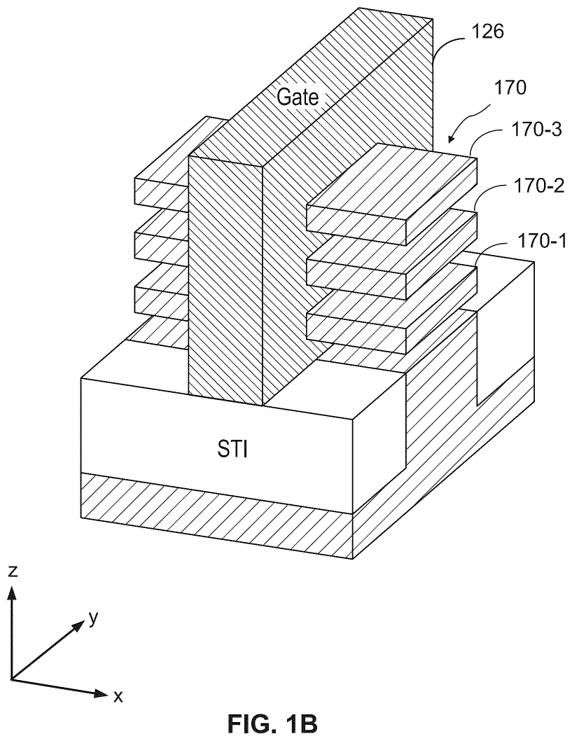

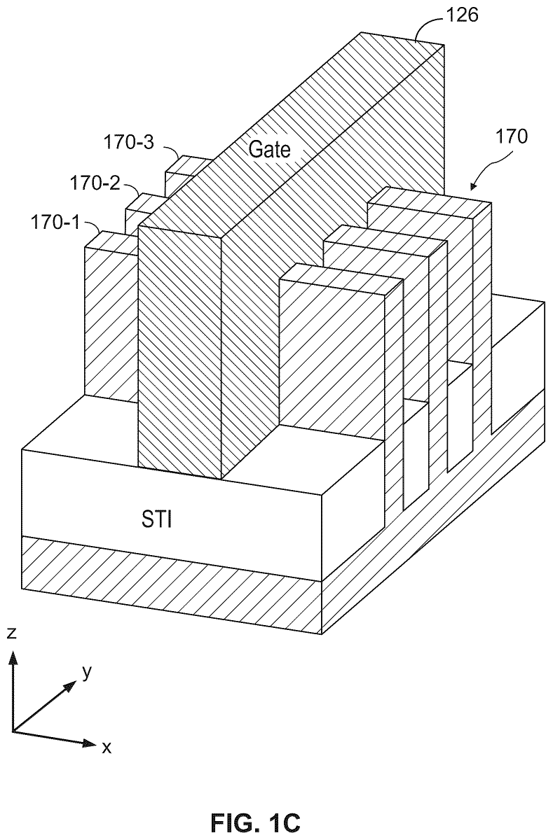

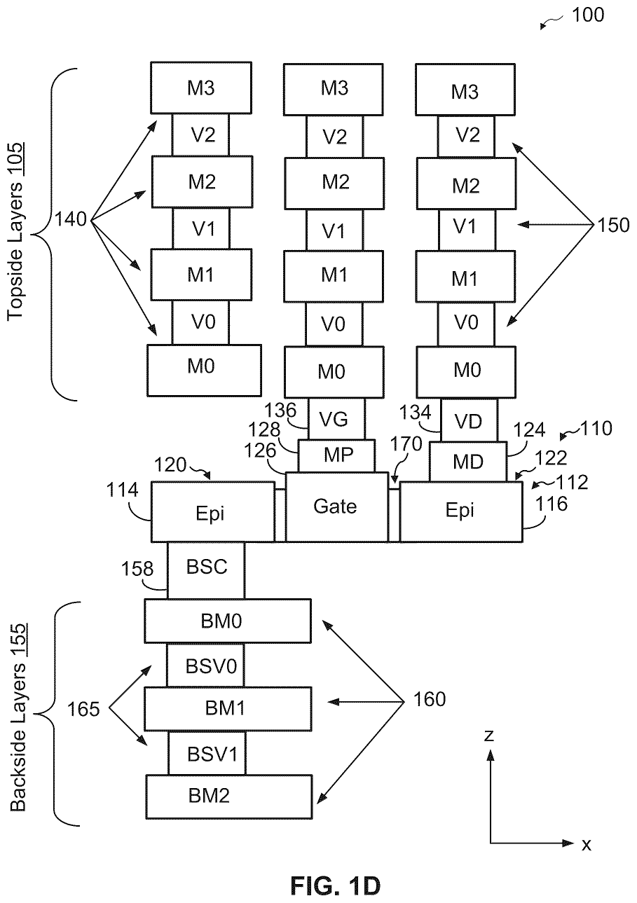

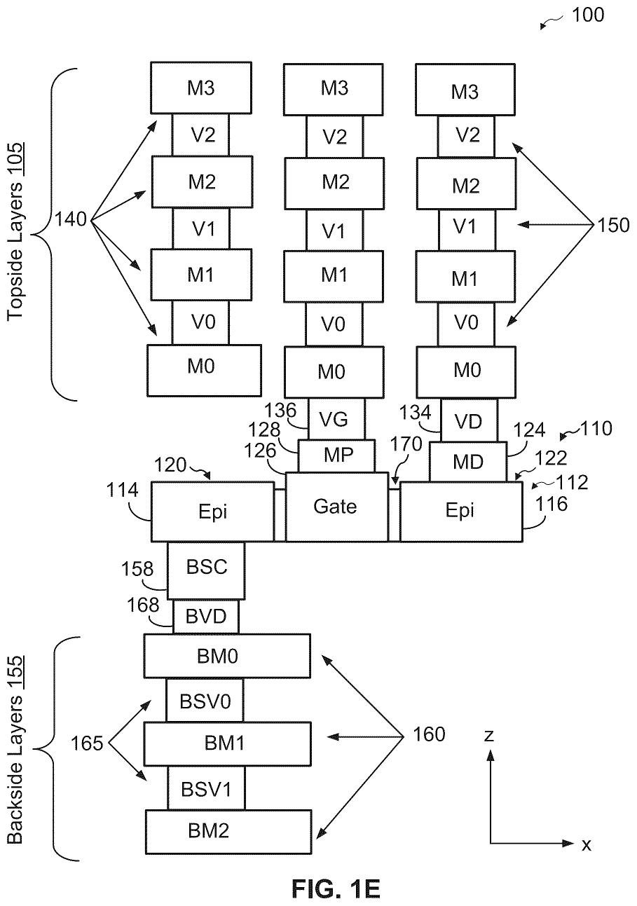

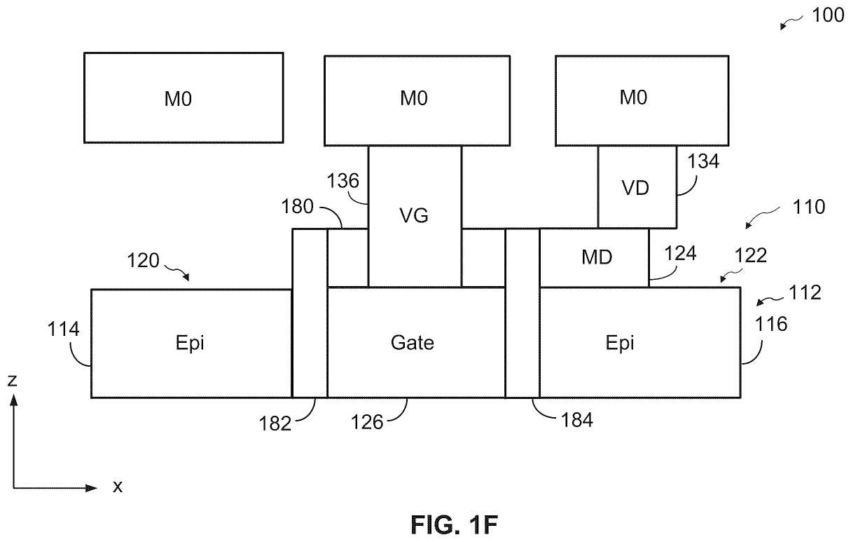

FIG. 1A shows a side view of an example of a chip 100 (e.g., a die) including a transistor 110 and multiple topside layers 105 (also referred to as frontside layers) according to certain aspects. Although one transistor 110 is shown in FIG. 1A for simplicity, it is to be appreciated that the chip 100 includes many transistors. As discussed further below, the transistor 110 may be implemented using a gate-all-around field effect transistor (FET) process, a fin field-effect transistor (FinFET) process, or another type of process. The topside layers 105 are above the transistor 110 in the z direction shown in FIG. 1A. The transistor 110 and the topside layers 105 may be formed on a semiconductor substrate 108 (e.g., silicon substrate).

In the example shown in FIG. 1A, the transistor 110 includes a diffusion region 112 and a gate 126 on the diffusion region 112. The diffusion region 112 may also be referred to as an oxide diffusion region, an active region, active diffusion, active (RX), or another term. The gate 126 may be formed on the diffusion region 112, and may include a gate metal (e.g., a high-k metal gate (HKMG)), polysilicon, and/or another gate material. The diffusion region 112 includes one or more channels 170 extending in the x direction in FIG. 1A, where the x direction is perpendicular to the z direction. As used herein, a “channel” is a structure that conducts current between a source and a drain of a transistor. For a gate-all-around FET process, the diffusion region 112 may correspond to an area of the chip 100 where one or more nanosheets are formed, in which the gate 126 is formed around a portion of the one or more nanosheets to provide the one or more channels 170. In this example, portions of the one or more nanosheets outside of the gate 126 may be cut and epi layers may be coupled to opposite sides of the one or more channels 170, as discussed further below.

For the example of a gate-all-around FET process, the gate 126 may surround each of the one or more channels 170 (also referred to as ribbons) on four sides. In this regard, FIG. 1B shows a perspective view in which the one or more channels 170 include channels 170-1, 170-2, and 170-3 where each of the channels 170-1, 170-2, and 170-3 is surrounded on four sides by the gate 126. Each of the channels 170-1, 170-2, and 170-3 may include a nanosheet, a nanowire, or the like. In this example, the channels 170-1, 170-2, and 170-3 are stacked vertically and are spaced apart from one another in the z direction. However, it is to be appreciated that the present disclosure is not limited to this example. In some implementations, the chip 100 may include shallow trench isolation (STI) to reduce leakage between devices on the chip 100. In other implementations, the STI may be omitted.

For the example of a finFET process, the gate 126 may surround each of the one or more channels 170 on three sides. In this regard, FIG. 1C shows a perspective view in which the one or more channels 170 include channels 170-1, 170-2, and 170-3 where each of the channels 170-1, 170-2, and 170-3 is surrounded on three sides by the gate 126. In this example, each of the channels 170-1, 170-2, and 170-3 is orientated vertically, and the channels 170-1, 170-2, and 170-3 are spaced apart from one another in the y direction. The channels for a finFET process may also be referred to as fins.

Returning to FIG. 1A, the transistor 110 may include a first epitaxial (epi) layer 114 and a second epi layer 116 in which the gate 126 is disposed between the first epi layer 114 and the second epi layer 116. The first epi layer 114 is coupled to the one or more channels 170 on one side of the gate 126 to provide a first source/drain 120. The second epi layer 116 is coupled to the one or more channels 170 on the other side of the gate 126 to provide a second source/drain 122. An epi layer may also be referred to as simply epi or another term. As used herein, the term “source/drain” means a source, a drain, or both a source and a drain.

As shown in FIG. 1A, the first epi layer 114 and the second epi layer 116 are located on opposite sides of the gate 126. Each of the first epi layer 114 and the second epi layer 116 may include grown or deposited silicon, a silicon-based material (e.g., silicon-germanium), or any combination thereof. In this example, the gate 126 controls the conductivity between the first source/drain 120 and the second source/drain 122 based on a voltage applied to the gate 126. The transistor 110 may include a first spacer (not shown in FIG. 1A) between the gate 126 and the first epi layer 114 and a second spacer (not shown in FIG. 1A) between the gate 126 and the second epi layer 116.

In this example, the chip 100 includes a topside contact 124 formed on a top surface of the second source/drain 122. A top surface may also be referred to as a frontside surface. The contact 124 may be formed (i.e., patterned) from a topside contact layer using, for example, lithographic and etching processes. The contact 124 may be referred to as a metal-diffusion (MD) contact, contact active (CA), or another term. The chip 100 may also include a gate contact 128 formed on the gate 126. The gate contact 128 may be referred to as a metal-poly (MP) contact or another term. The gate contact 128 may be omitted in some implementations. A topside contact may also be referred to as a frontside contact or another term.

In this example, the topside layers 105 include topside metal layers 140. A topside metal layer may also be referred to as a frontside metal layer, a metal interconnect, or another term. The topside metal layers 140 may be patterned (e.g., using lithography and etching) to provide signal routing for the transistor 110 and other transistors (not shown in FIG. 1A) integrated on the chip 100. In some implementations, the topside metal layers 140 may also be patterned to form a power distribution network including supply rails for distributing power to the transistor 110 and other transistors integrated on the chip 100. In other implementations, the power distribution network is provided using backside layers (e.g., to reduce routing congestion in the topside layers 105), as discussed further below with reference to FIG. 1D.

In the example in FIG. 1A, the bottom-most topside metal layer among the topside metal layers 140 is referred to as metal layer M0. The topside metal layer immediately above metal layer M0 is referred to as metal layer M1, the topside metal layer immediately above metal layer M1 is referred to as metal layer M2, the topside metal layer immediately above metal layer M2 is referred to as metal layer M3, and so forth. Although four topside metal layers 140 (i.e., M0 to M3) are shown in FIG. 1A for case of illustration, it is to be appreciated that the topside layers 105 may include additional topside metal layers above metal layer M3. It is to be appreciated that the present disclosure is not limited to the nomenclature in which the bottom-most topside metal layer is referred to as metal layer M0. For instance, in another example, the bottom-most topside metal layer may be referred to as metal layer M1 instead of metal layer M0.

The topside layers 105 also includes vias 150 that provide coupling between the topside metal layers 140. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip also includes a via 136 disposed between the gate contact 128 and metal layer M0, in which the via 136 couples the gate contact 128 (and hence the gate 126) to metal layer M0. For implementations where the gate contact 128 is omitted, the via 136 may be disposed between the gate 126 and metal layer M0 without an intervening gate contact. Also, in this example, the chip 100 includes a via 134 disposed between the contact 124 and metal layer M0, in which the via 134 couples the contact 124 to metal layer M0. In some implementations, the via 134 may be omitted with the contact 124 directly contacting metal layer M0.

In certain aspects, most or all of the semiconductor substrate 108 is removed to form backside layers under the transistors (e.g., transistor 110) on the chip 100. As used herein, “most” of the semiconductor substrate 108 means at least 90 percent of the semiconductor substrate 108. For example, after formation of the transistors and the topside layers 105, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off (e.g., using chemical mechanical polishing (CMP)). Backside layers may then be formed under the transistors on the chip 100.

In this regard, FIG. 1D shows an example of backside layers 155 formed under the transistor 110. In this example, the backside layers 155 include backside metal layers 160. The backside metal layers 160 may be patterned (e.g., using lithography and etching) to form a power distribution network including supply rails for distributing power to the transistor 110 and other transistors on the chip 100.

In the example in FIG. 1D, the top-most backside metal layer among the backside metal layers 160 is referred to as backside metal layer BM0. The backside metal layer immediately below backside metal layer BM0 is referred to as backside metal layer BM1, the backside metal layer immediately below backside metal layer BM1 is referred to as backside metal layer BM2, and so forth. Although three backside metal layers 160 (i.e., BM0 to BM2) are shown in FIG. 1D for case of illustration, it is to be appreciated that the backside layers 155 may include additional metal layers below backside metal layer BM2.

In the example in FIG. 1D, the chip 100 includes a backside contact 158 formed on a bottom surface (i.e., backside surface) of the first source/drain 120. The backside contact 158 may be formed (i.e., patterned) from a backside contact layer (labeled “BSC”) using, for example, lithographic and etching processes. The backside contact 158 is used to couple the first source/drain 120 to backside metal layer BM0. In some implementations, the backside contact 158 may directly contact backside metal layer BM0, as shown in the example in FIG. 1D. In other implementations, the backside contact 158 may be coupled to backside metal layer BM0 through an intervening via. In this regard, FIG. 1E shows an example in which the chip 100 includes a backside via 168 (labeled “BVD”) disposed between the backside contact 158 and backside metal layer BM0. In this example, the backside via 168 provides a space between the backside contact 158 and backside metal layer BM0 in the z direction.

In the examples in FIG. 1D and FIG. 1E, the backside layers 155 include vias 165 that provide coupling between the backside metal layers 160. In this example, the vias 165 include a via BSV0 that provides coupling between backside metal layer BM0 and backside metal layer BM1, and a via BSV1 that provides coupling between backside metal layer BM1 and backside metal layer BM2.

In certain aspects, the topside metal layers 140 are patterned (e.g., using lithography and etching) to provide signal routing for the transistor 110 and other transistors (not shown in FIG. 1A) integrated on the chip 100, and the backside metal layers 160 are patterned to form a power distribution network including supply rails for distributing power to the transistor 110 and the other transistors integrated on the chip 100. Moving the power distribution network to the backside layers 155 helps reduce routing congestion compared with the case in which the topside layers 105 are used for both signal routing and power distribution. It is to be appreciated that, in some implementations, both the topside metal layers 140 and the backside metal layers 160 may be used for signal routing.

In certain aspects, a protective dielectric layer may be deposited on the gate 126 to prevent gate-to-contact shorts. In this regard, FIG. 1F shows an example in which the chip 100 includes a dielectric cap 180 deposited on the top surface of the gate 126. The dielectric cap 180 helps prevent gate-to-contact shorts (e.g., due to misalignment of the contact 124), as discussed further below. In this example, the dielectric cap 180 may also be referred to as a self-aligned contact (SAC) cap or another term. The dielectric cap 180 may include silicon nitride or another dielectric material.

In the example shown in FIG. 1F, the chip 100 includes a first spacer 182 disposed between the gate 126 and the first epi layer 114, and a second spacer 184 disposed between the gate 126 and the second epi layer 116. A spacer may also be referred to as a sidewall spacer, an inner spacer, or another term. The spacers 182 and 184 and the dielectric cap 180 may be made of the same dielectric material or different dielectric materials.

In this example, the gate 126 (e.g., metal gate) and the dielectric cap 180 are disposed between the spacers 182 and 184. During processing, the gate 126 is recessed between the spacers 182 and 184 to form a recess (i.e., cavity) between the spacers 182 and 184 and above the gate 126. Dielectric material is then deposited in the recess to form the dielectric cap 180 (e.g., SAC cap) on top of the gate 126.

In this example, the one or more channels 170 (shown in FIGS. 1A to 1E) pass through the spacers 182 and 184 and the gate 126. Also, in this example, the gate via 136 passes through an opening in the dielectric cap 180 to make electrical contact with the gate 126.

FIG. 1F shows an example in which the contact 124 is misaligned (e.g., shifted to the left in FIG. 1F). During processing, the misalignment may cause a portion of the contact 124 (not shown in FIG. 1F) to land on the top surface of the dielectric cap 180. In this example, the dielectric cap 180 prevents a short between the contact 124 and the gate 126 by isolating the contact 124 from the gate 126 underneath the dielectric cap 180.

Although one gate 126 is shown in FIGS. 1A to IF, it is to be appreciated that the transistor 110 may include multiple gates arranged in parallel and coupled to one another (e.g., through metal layer M0 or another metal layer). A transistor with multiple gates may be referred to as a multi-gate transistor, a multi-finger transistor, or another term.

Transistors on the chip 100 may be organized into cells. Each cell may include one or more transistors that are arranged to provide a circuit (e.g., an inverter, a driver, a logic gate, combinational logic, a latch, a flip-flop, a bit cell (e.g., a static random-access memory (SRAM) bit cell), or another type of circuit. The layout of each cell may be specified (i.e., defined) in a standard cell library, which may be stored in a memory. The standard cell library may specify (i.e., define) the layout of each one of various cells that can be placed (i.e., laid out) on the chip 100 for a particular process. The chip 100 may include multiple instances of a particular cell defined in the standard cell library. The layout of each cell defined in the standard cell library may include the layout of gates, diffusion regions, and contacts in the cell.

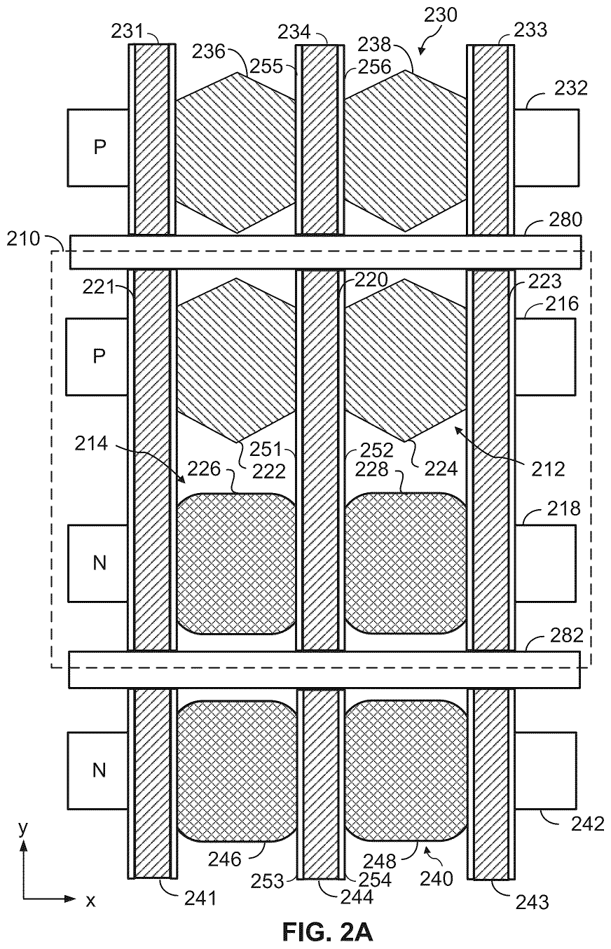

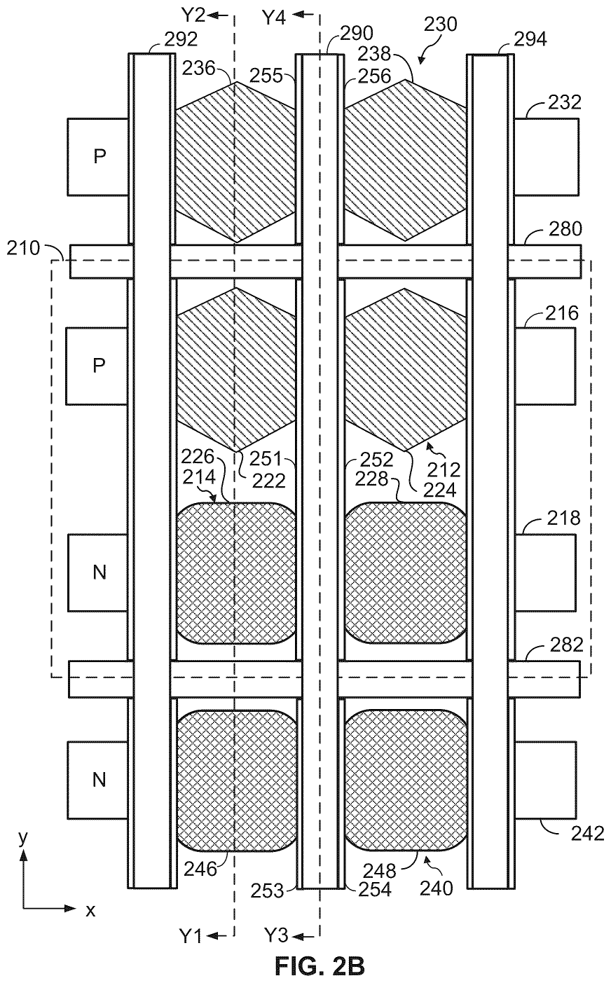

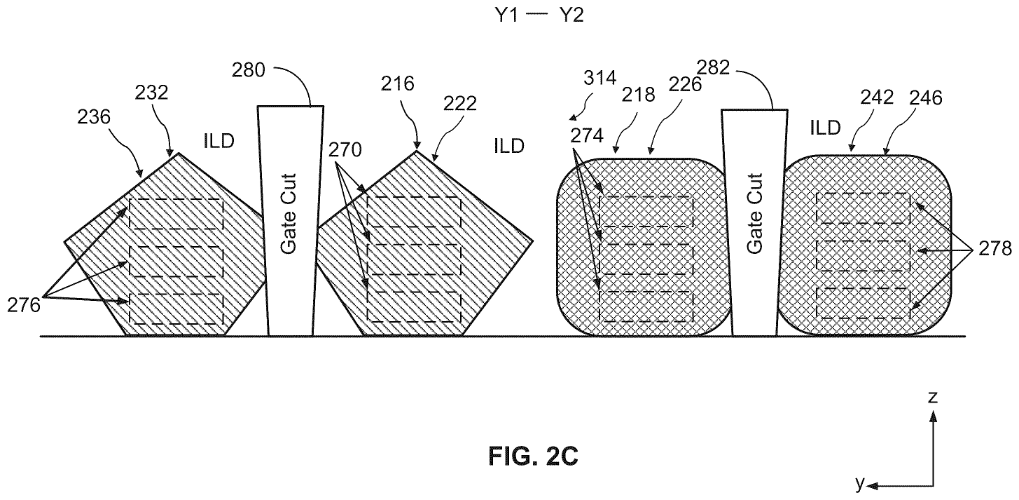

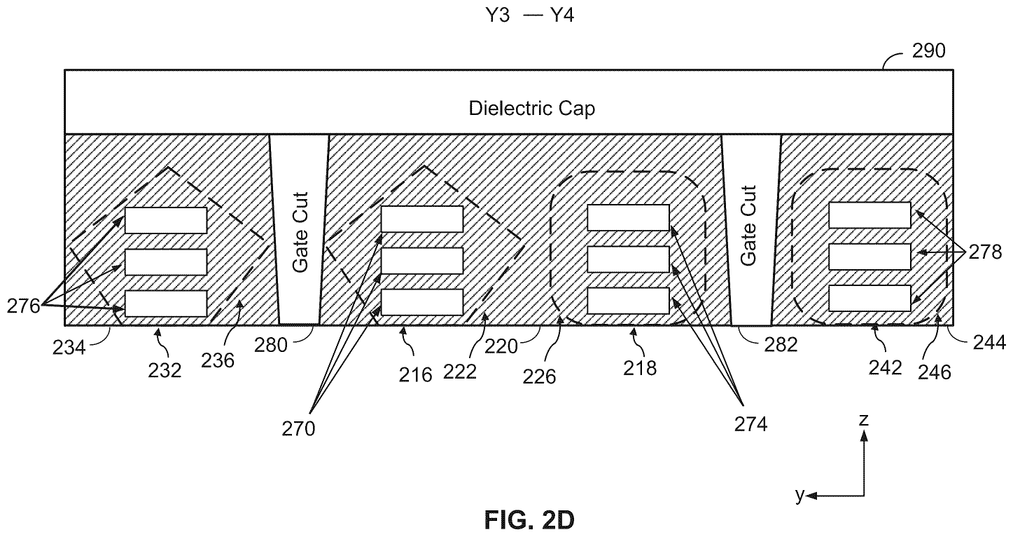

FIG. 2A shows a top view of an exemplary cell 210 integrated on the chip 100 according to certain aspects. In this example, the cell 210 includes a first diffusion region 216 extending in the x direction and a second diffusion region 218 extending in the x direction, in which the first diffusion region 216 and the second diffusion region 218 are spaced apart in the y direction, which is perpendicular to the x direction and the z direction. Each of the diffusion regions 216 and 218 may include one or more respective channels (e.g., a respective instance of the one or more channels 170) extending in the x direction. In this example, the first diffusion region 216 may be a p-type diffusion region and the second diffusion region 218 may be an n-type diffusion region (e.g., to provide the cell 210 with complementary transistors). However, it is to be appreciated that the present disclosure is not limited to this example. It is also to be appreciated that the cell 210 may include more than two diffusion regions in other implementations.

The cell 210 includes a gate 220 extending in the y direction over the first diffusion region 216 and the second diffusion region 218. The gate 220 may include a metal (e.g., a high-k metal gate (HKMG)), polysilicon, and/or another gate material. For a gate-all-around FET process, the gate 126 may surround each of the one or more channels of the first diffusion region 216 on four sides, and surround each of the one or more channels of the second diffusion region 218 on four sides (e.g., as illustrated in the example in FIG. 1B). For a finFET process, the gate 126 may surround each of the one or more channels of the first diffusion region 216 on three sides, and surround each of the one or more channels of the second diffusion region 218 on three sides (e.g., as illustrated in the example in FIG. 1C).

The first diffusion region 216 includes epitaxial (epi) layer 222, one or more channels 270 (shown in FIG. 2D), and epi layer 224. The second diffusion region 218 includes epi layer 226, one or more channels 274 (shown in FIG. 2D), and epi layer 228. In the discussion below, the epi layer 222 is referred to as the first epi layer 222, the epi layer 226 is referred to as the second epi layer 226, the epi layer 224 is referred to as the third epi layer 224, and the epi layer 228 is referred to as the fourth epi layer 228. Each the first epi layer 222, the second epi layer 226, the third epi layer 224, and the fourth epi layer 228 may include epitaxially grown or deposited silicon, a silicon-based material (e.g., silicon-germanium), or any combination thereof. The gate 220 is disposed between the first epi layer 222 and the third epi layer 224, in which the one or more channels 270 (shown in FIG. 2D) pass through the gate 220 and are coupled between the first epi layer 222 and the third epi layer 224. The gate 220 is also disposed between the second epi layer 226 and the fourth epi layer 228, in which the one or more channels 274 (shown in FIG. 2D) pass through the gate 220 and are coupled between the second epi layer 226 and the fourth epi layer 228. The first epi layer 222 and the second epi layer 226 are spaced apart in the y direction, and the third epi layer 224 and the fourth epi layer 228 are spaced apart in the y direction, as shown in FIG. 2A.

In this example, the first diffusion region 216 and the gate 220 form a first transistor 212 (e.g., a p-type field effect transistor (PFET)), in which the first epi layer 222 provides a first source/drain and the third epi layer 224 provides a second source/drain of the first transistor 212. The second diffusion region 218 and the gate 220 form a second transistor 214 (e.g., an n-type field effect transistor (NFET)), in which the second epi layer 226 provides a first source/drain and the fourth epi layer 228 provides a second source/drain for the second transistor 214.

In this example, the first transistor 212 and the second transistor 214 share the gate 220 (i.e., the gate 220 is common to both transistors 212 and 214). Two or more transistors may share a common gate in various types of cells. For example, complementary transistors (e.g., a PFET and an NFET) may share a common gate in an inverter cell, an SRAM cell, or another type of cell. For the example of an inverter cell, the common gate of the complementary transistors may be coupled to the input of the inverter cell. For the example of an SRAM cell, the common gate of the complementary transistors (e.g., a pull-up (PU) transistor and a pull-down (PD) transistor) may be coupled to a source/drain of a pass-gate (PG) transistor in the SRAM cell.

In this example, the chip 100 also includes a third diffusion region 232 extending in the x direction and a gate 234 extending in the y direction over the third diffusion region 232. The third diffusion region 232 includes a fifth epi layer 236, one or more channels 276 (shown in FIG. 2D), and a sixth epi layer 238. The gate 234 is disposed between the fifth epi layer 236 and the sixth epi layer 238, in which the one or more channels 276 pass through the gate 234 and are coupled between the fifth epi layer 236 and the sixth epi layer 238. In this example, the gate 234 and the third diffusion region 232 form a third transistor 230 (e.g., a PFET) located above the cell 210 in the y direction. The third transistor 230 may be part of a cell adjacent to the cell 210.

In this example, the chip 100 also includes a fourth diffusion region 242 extending in the x direction and a gate 244 extending in the y direction over the fourth diffusion region 242. The fourth diffusion region 242 includes a seventh epi layer 246, one or more channels 278 (shown in FIG. 2D), and an eighth epi layer 248. The gate 244 is disposed between the seventh epi layer 246 and the eighth epi layer 248, in which the one or more channels 278 pass through the gate 244 and are coupled between the seventh epi layer 246 and the eighth epi layer 248. In this example, the gate 244 and the fourth diffusion region 242 form a fourth transistor 240 (e.g., a NFET) located below the cell 210 in the y direction. The fourth transistor 240 may be part of a cell adjacent to the cell 210.

As shown in FIG. 2A, each epi layer extends laterally in the y direction. This is because the epitaxial process (e.g., epitaxial growth process) for each epi layer forms (e.g., grows) the epi layer in both the z and y directions. As discussed further below, the lateral growth of the epi layers in the y direction can potentially lead to shorts between adjacent epi layers. The spaces between adjacent epi layers are filled with an interlayer dielectric (ILD).

In the example illustrated in FIG. 2A, the chip 100 includes additional gates 221, 223, 231, 233, 241, and 243 spaced apart from the gates 220, 234, and 244 in the x direction (e.g., at a uniform pitch). The additional gates 221, 223, 231, 233, 241, and 243 may be dummy gates (also known as non-functional gates). In other implementations, the transistors 212, 214, 230, and 240 may be multi-gate transistors, and the additional gates 221, 223, 231, 233, 241, and 243 may be additional gates of the transistors 212, 214, 230, and 240. In other implementations, the additional gates 221, 223, 231, 233, 241, and 243 may be replaced with diffusion breaks (e.g., single diffusion breaks or double diffusion breaks).

It is to be appreciated that the chip 100 may include one or more additional epi layers (not shown). For example, the chip 100 may include one or more epi layers (not shown) to the left of the gate 221 and/or one or more epi layers (not shown) to the right of the gate 223.

In the example illustrated in FIG. 2A, the chip 100 also includes spacers between the gates and the epi layers. A spacer may also be referred to as an inner spacer, a sidewall spacer, or another term. In this example, the chip 100 includes a spacer 251 disposed between the gate 220 and the epi layers 222 and 226, and a spacer 252 disposed between the gate 220 and the epi layers 224 and 228. The chip 100 may also include a spacer 253 disposed between the gate 244 and the epi layer 246, and a spacer 254 disposed between the gate 244 and the epi layer 248. The chip 100 may also include a spacer 255 disposed between the gate 234 and the epi layer 236, and a spacer 256 disposed between the gate 234 and the epi layer 238. In this example, each of the spacers 251, 252, 253, 254, 255, and 256 extends in the y direction. The chip 100 may also include spacers on both sides of each of the gates 221, 223, 231, 233, 241, and 243. The spacers may include silicon oxide, silicon nitride, silicon carbon oxynitride (SiCON), etc. However, it is to be appreciated that the present disclosure is not limited to this example.

In certain aspects, the gates 220, 234, and 244 may initially be part of a single gate that is cut into the gates 220, 234, and 244 using a gate cutting process. The gate cutting process may include patterning and etching to cut the single gate at desired locations to form the gates 220, 234, and 244. In this regard, FIG. 2A shows an example of a first gate cut structure 280 and a second gate cut structure 282 according to certain aspects.

In this example, the first gate cut structure 280 extends in the x direction and separates the gates 220 and 234. The first gate cut structure 280 may also separate the gates 221 and 231 and separate the gates 223 and 233. The first gate cut structure 280 may be formed, for example, by etching a trench that extends in the x direction and cuts through the single gate discussed above and then filling the trench with a dielectric material. The gate cut structure 280 may also cut through the tips of the epi layers 236, 222, 224, and 238.

In this example, the second gate cut structure 282 extends in the x direction and separates the gates 220 and 244. The second gate cut structure 282 may also separate the gates 221 and 241 and separate the gates 223 and 243. The second gate cut structure 282 may be formed, for example, by etching a trench that extends in the x direction and cuts through the single gate discussed above and then filling the trench with a dielectric material.

FIG. 2B shows an example in which the chip 100 also includes a first dielectric cap 290 formed on the top surfaces of the gates 220, 234, and 244 and extending in the y direction according to certain aspects. For example, the first dielectric cap 290 may be used to prevent gate-to-contact shorts (e.g., due to contact misalignment). In this example, the first dielectric cap 290 may also be referred to as a SAC cap. The first dielectric cap 290 may include silicon nitride or another dielectric material. The first dielectric cap 290 and the spacers 251 and 252 may include the same dielectric material or different dielectric materials. The first dielectric cap 290 may extend over the first gate cut structure 280 between the gates 220 and 234 and the second gate cut structure 282 between the gates 220 and 244 (as shown in the example in FIG. 2D), but is not limited to this example. In this example, the gate 220 may be recessed between the spacers 251 and 252 (e.g., as illustrated in the example in FIG. 1F), in which the first dielectric cap 290 is formed in a recess (i.e., cavity) formed between the spacers 251 and 252 and above the gate 220. Note that the reference numbers for the gates are not shown in FIG. 2B for case of illustration.

In this example, the chip 100 may also include a second dielectric cap 292 formed on the top surfaces of the gates 221, 231, and 241 and a third dielectric cap 294 formed on the top surfaces of the gates 223, 233, and 243, where each of the dielectric caps 292 and 294 extends in the y direction. However, it is to be appreciated that the present disclosure is not this example. For example, in other implementations, the additional gates 221, 223, 231, 233, 241, and 243 may be replaced with diffusion breaks.

FIG. 2C shows a cross-sectional view taken along cross-section line Y1-Y2 in FIG. 2B, which intersects the first epi layer 222 and the second epi layer 226. In this example, the first diffusion region 216 and the second diffusion region 218 are formed using a gate-all-around FET process, but are not limited to this example. In this example, the first epi layer 222 is coupled to the one or more channels 270 passing through the gate 220, and the second epi layer 226 is coupled to the one or more channels 274 passing through the gate 220. Note that the gate 220 and the one or more channels 270 and 274 are not intersected by the cross-section line Y1-Y2 in this example. In FIG. 2C, the one or more channels 270 are shown in dashed line to indicate the position of the one or more channels 270 in the z direction and the y direction, and the one or more channels 274 are shown in dashed line to indicate the position of the one or more channels 274 in the z direction and the y direction.

FIG. 2C shows an example in which the first epi layer 222 and the second epi layer 226 have different shapes. This may be due to, for example, the first epi layer 222 and the second epi layer 226 being formed using different epitaxial processes and/or materials. For example, the first epi layer 222 may include silicon-germanium (SiGe) and the second epi layer 226 may include silicon. However, it is to be appreciated that the present disclosure is not limited to this example. In other implementations, the first epi layer 222 and the second epi layer 226 may have substantially the same shape. Also, in other implementations, the first epi layer 222 may have a shape that is different from the exemplary shape shown in FIG. 2C and/or the second epi layer 226 may have a shape that is different from the exemplary shape shown in FIG. 2C. In other words, the first epi layer 222 and the second epi layer 226 are not limited to a particular shape.

FIG. 2C also shows the first gate cut structure 280 disposed between the first epi layer 222 and the fifth epi layer 236, and the second gate cut structure 282 disposed between the second epi layer 226 and the seventh epi layer 246. This is because the first gate cut structure 280 extends in the x direction between the epi layers 222 and 236, and the second gate cut structure 282 extends in the x direction between the epi layers 226 and 246, as shown in the example in FIG. 2B.

FIG. 2D shows a cross-sectional view taken along cross-section line Y3-Y4 in FIG. 2B. As shown in FIG. 2D, the one or more channels 270 of the first transistor 212 and the one or more channels 274 of the second transistor 214 pass through the gate 220, which is shared by the transistors 212 and 214. In this example, each of the one or more channels 270 is surrounded by the gate 220 on four sides, and each of the one or more channels 274 is surrounded by the gate 220 on four sides. Note that the epi layers 222 and 226 are not intersected by the cross-section line Y1-Y2 in this example. In FIG. 2D, the first epi layer 222 is shown in dashed line to indicate the position of the first epi layer 222 in the z direction and the y direction, and the second epi layer 226 is shown in dashed line to indicate the position of the second epi layer 226 in the z direction and the y direction.

FIG. 2D also shows the one or more channels 276 of the third transistor 230 passing through the gate 234, and the one or more channels 278 of the fourth transistor 240 passing through the gate 244. The epi layers 236 and 246 are shown in dashed lines to indicate their positions in the z direction and the y direction.

Each of the one or more channels 270, 274, 276, and 278 may include one or more respective nanosheets extending in the x direction, one or more respective nanowires extending in the x direction, one or more respective fins extending in the x direction, or the like. It is to be appreciated that the one or more channels 270, 274, 276, and 278 are not limited to the exemplary cross-sectional shapes shown in the example in FIG. 2D, and may have other shapes in other implementations. In the example shown in FIG. 2D, each of the one or more channels 270, 274, 276, and 278 includes three channels. However, it is to be appreciated that each of the one or more channels 270, 274, 276, and 278 may include another number of channels in other implementations.

FIG. 2D also shows the first gate cut structure 280 separating the gates 220 and 234, and the second gate cut structure 282 separating the gates 220 and 244. As shown in FIG. 2D, each of the gate cut structures 280 and 282 extends in the z direction to isolate the respective gates.

FIG. 2D also shows the dielectric cap 290 (e.g., SAC cap) extending in the y direction on the tops of the gates 220, 234, and 244. As shown in FIG. 2D, the dielectric cap 290 also extends over the first gate cut structure 280 between the gates 220 and 234 and the second gate cut structure 282 between the gates 220 and 244 in this example.

It is desirable to reduce the heights of cells on the chip 100 in the y direction in order to fit a larger number of cells on the chip 100. For example, the height of the cell 210 may be reduced by reducing the spacing between first epi layer 222 and the second epi layer 226, which allows the transistors 212 and 214 to be moved closer together. However, reducing the spacing between the epi layers 222 and 226 may significantly increase the risk of the epi layers 222 and 226 touching and causing an epi-cpi short. For example, the widths of the epi layers in the y direction may vary due to process variation. As a result, the epi-epi spacing (i.e., spacing between adjacent epi layers) may need to be equal to or greater than a minimum spacing to ensure that process variation does not result in an unintentional epi-epi shorts. The minimum spacing requirement limits the ability to reduce the spacing between the epi layers 222 and 226 to reduce the cell height.

To overcome the above limitations, aspects of the present disclosure provide a dielectric wall that electrically isolates adjacent epi layers, allowing the corresponding diffusion regions (i.e., active regions) to be spaced closer together to achieve cell height down scaling. In certain aspects, the adjacent epi layers correspond to transistors that share a common gate. In these aspects, the dielectric wall is formed by etching a trench that extends in the x direction between the adjacent epi layers and filling the trench with a dielectric material. In these aspects, the dielectric cap on the shared gate (i.e., common gate) provides an etch stop that prevents the etching process from etching the shared gate, thereby retaining the shared gate. The above features and other features of the present disclosure are discussed further below.

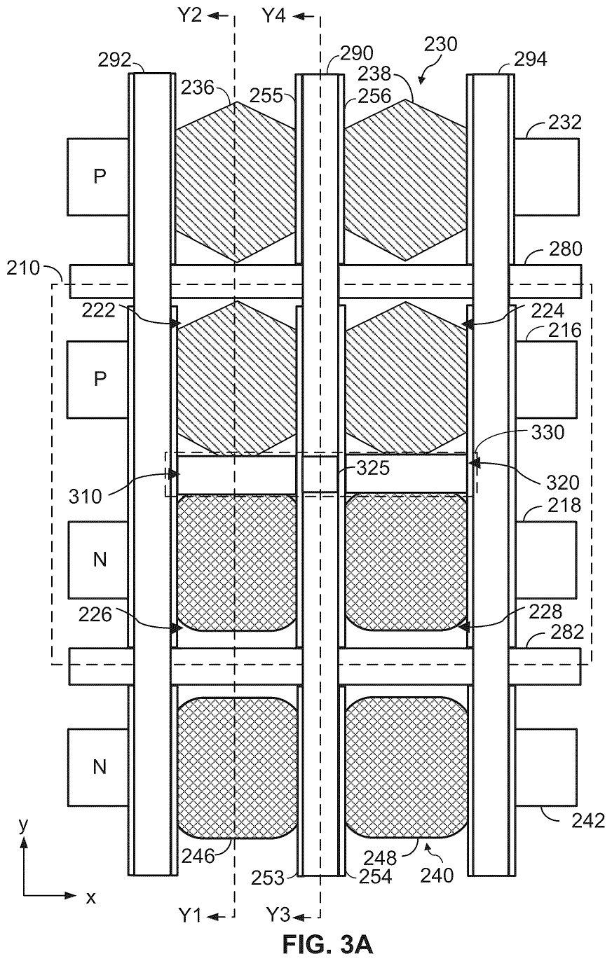

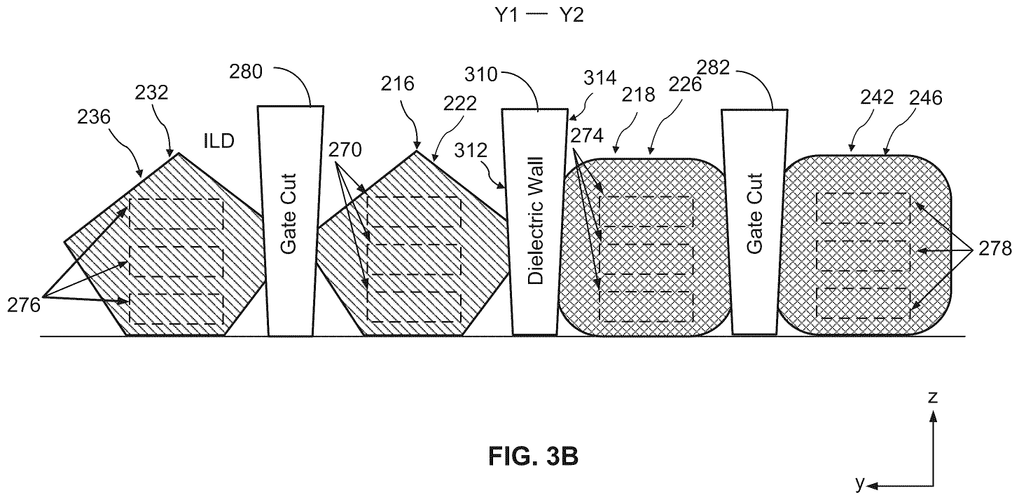

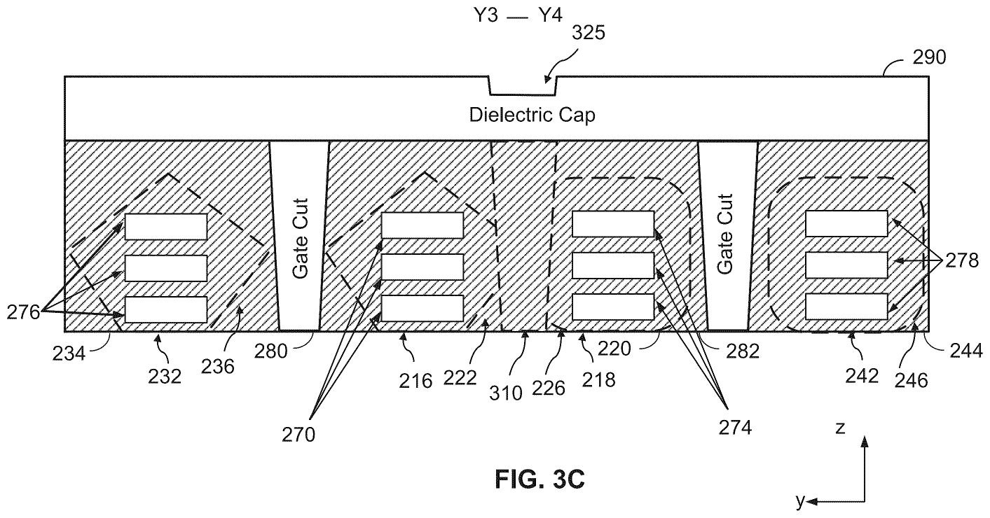

FIG. 3A shows a top view in which the chip 100 includes a first dielectric wall 310 and a second dielectric wall 320 according to certain aspects. The first dielectric wall 310 extends in the x direction between the first epi layer 222 and the second epi layer 226, and the second dielectric wall 320 extends in the x direction between the third epi layer 224 and the fourth epi layer 228. As used herein, a “dielectric wall” refers to a structure extending in the z direction and the x direction, and is made of substantially one or more dielectric materials, such as silicon dioxide (SiO2), silicon nitride (Si3N4), silicon carbon oxynitride (SiCON), etc. A dielectric wall may also be referred to as a dielectric barrier, dielectric isolation, an epi-epi dielectric wall, an isolation structure, or another term.

In this example, the dielectric walls 310 and 320 are formed using a frontside etching process. FIG. 3A shows an example of the etch pattern 330 for the frontside etching. As used herein, an “etch pattern” defines the area of the chip 100 that is etched (e.g., using a photolithographic process). The etching process may include a reactive ion etching process, a plasma etching process, and/or another type of suitable etching process. In the example in FIG. 3A, the etch pattern 330 extends in the x direction and overlaps the first dielectric cap 290. It is to be appreciated that the etch pattern 330 may extend further in the x direction than shown in the example in FIG. 3A.

In this example, the etching process etches a first trench between the first epi layer 222 and the second epi layer 226, in which the first trench is filled with the dielectric material discussed above to form the first dielectric wall 310. The etching process also etches a second trench between the third epi layer 224 and the fourth epi layer 228, in which the second trench is filled with the dielectric material discussed above to form the second dielectric wall 320.

In this example, a portion of the first dielectric cap 290 is exposed to the frontside etching since the etch pattern 330 overlaps the dielectric cap 290. In this example, the first dielectric cap 290 includes a dielectric material (e.g., silicon nitride) that is etched at a slower rate than the ILD between the epi layers 222 and 226 and between the epi layers 224 and 228 (e.g., the etch selectivity is higher for the ILD than the dielectric cap 290). As a result, the first dielectric cap 290 is etched to a shallower depth than the depths of the trenches forming the dielectric walls 310 and 320.

In the example shown in FIG. 3A, a small portion of the first dielectric cap 290 is etched away forming a divot 325 (i.e., recess) in the first dielectric cap 290 between the dielectric walls 310 and 320. In this example, the depth of the divot 325 in the z direction is smaller than the thickness of the first dielectric cap 290 in the z direction. As a result, the etching does not completely etch through the first dielectric cap 290, thereby protecting the underlying gate 220 from the etching. Since the gate 220 is protected from the etching by the first dielectric cap 290, the shared gate 220 of the transistors 212 and 214 is retained. In this regard, the first dielectric cap 290 provides an etch stop for the gate 220 that stops the etching from reaching the gate 220.

FIG. 3B shows a cross-sectional view taken along cross-section line Y1-Y2 in FIG. 3A, which intersects the first epi layer 222, the second epi layer 226, and the first dielectric wall 310. As shown in FIG. 3B, the first dielectric wall 310 is disposed between the first epi layer 222 and the second epi layer 226 to provide isolation between the first epi layer 222 and the second epi layer 226. The isolation prevents the first epi layer 222 and the second epi layer 226 from shorting, which allows the first diffusion region 216 and the second diffusion region 218 to be spaced closer together to scale down the height of the cell 210 without unintentionally shorting the first epi layer 222 and the second epi layer 226.

In this example, a first side 312 of the first dielectric wall 310 abuts the first epi layer 222 and a second side 314 of the first dielectric wall 310 abuts the second epi layer 226, in which the first side 312 and the second side 314 are opposite sides of the first dielectric wall 310. As shown in FIG. 3B, the first dielectric wall 310 extends in the z direction between the first epi layer 222 and the second epi layer 226. It is to be appreciated that the first dielectric wall 310 is not limited to the depth shown in the example in FIG. 3B. For example, the first dielectric wall 310 may extend further in the z direction in some implementations. It is also to be appreciated that the height of the first dielectric wall 310 in the z direction may be higher than shown in the example in FIG. 3B in some implementations.

FIG. 3B also shows the fifth epi layer 236, the seventh epi layer 246, the first gate cut structure 280, and the second gate cut structure 282 discussed above with reference to FIG. 2C. Since these structures are described above with reference to FIG. 2C, the description of these structures is not repeated here for brevity.

FIG. 3C shows a cross-sectional view taken along cross-section line Y3-Y4 in FIG. 3A. As shown in FIG. 3C, the one or more channels 270 and the one or more channels 274 pass through the gate 220, which is shared by the first and second transistors 212 and 214. Also, the one or more channels 276 pass through the gate 234, and the one or more channels 278 pass through the gate 244.

Note that FIG. 3C does not intersect the first dielectric wall 310 since the first dielectric wall 310 does not pass through the gate 220. In FIG. 3C, the first dielectric wall 310 is shown in dashed line to indicate that position of the first dielectric wall 310 in the y direction and the z direction.

FIG. 3C also shows the divot 325 (i.e., recess) in the first dielectric cap 290 between the dielectric walls 310 and 320 in the x direction. In this example, the divot 325 is aligned with the first dielectric wall 310 in the y direction. As shown in FIG. 3B, the depth of the divot 325 in the z direction is smaller than the thickness of the first dielectric cap 290 in the z direction, and therefore, does not reach the underlying gate 220. As a result, the first dielectric cap 290 protects the underlying gate 220 from the etching used to form the trenches for the first dielectric wall 310 and the second dielectric wall 320, thereby retaining the shared gate 220 of the transistors 212 and 214.

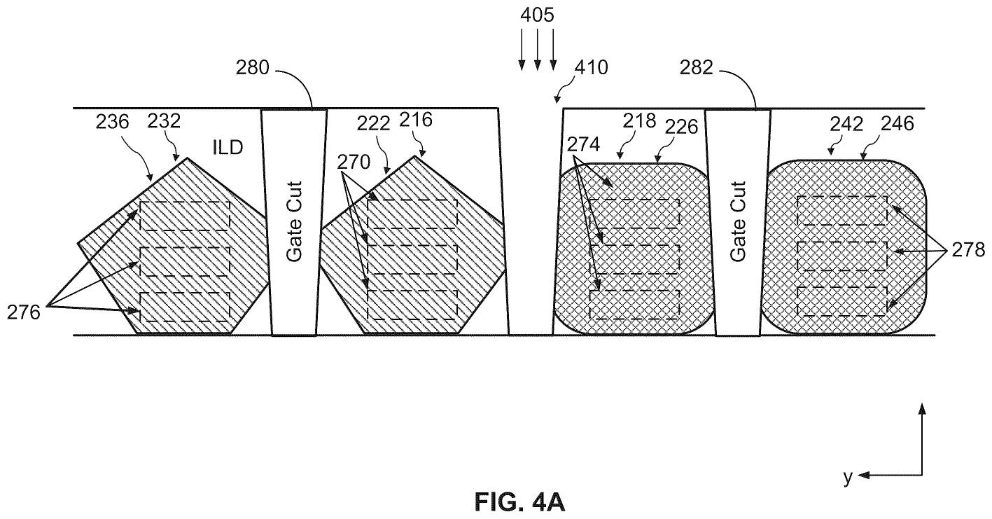

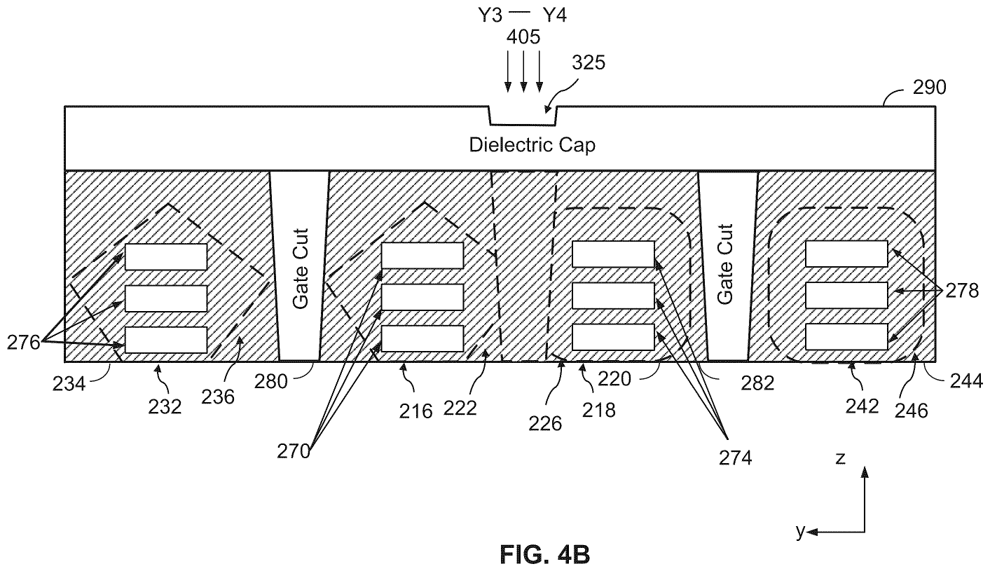

FIGS. 4A and 4B illustrate an example of the frontside etching process used to form the trenches for the dielectric walls 310 and 320.

FIG. 4A shows a cross-sectional view taken along cross-section line Y1-Y2 in which a trench 410 is etched between the epi layers 222 and 226 from the frontside. Another trench (not shown) may be etched between the epi layers 224 and 228 on the other side of the gate 220. The area of the chip 100 that is etched is defined by the etch pattern 330 discussed above.

The etching process may include a reactive ion etching process, a plasma etching process, and/or another type of suitable etching process. In FIG. 4A, the direction 405 of the etching is indicated by the arrows pointing into the opening of the trench 410. As shown in FIG. 4A, the etching process etches through the ILD between the epi layers 222 and 226. The etching process may also etch through (i.e., cut through) portions of the epi layers 222 and 226, as discussed further below.

In the example in FIG. 4A, the trench 410 is between the first epi layer 222 and the second epi layer 226, and cuts through a portion of the first epi layer 222 and a portion of the second epi layer 226. In cases where the adjacent sides of the first epi layer 222 and the second epi layer 226 touch before the frontside etching to form the trench 410, the frontside etching etches away the portions of the epi layers 222 and 226 that are touching, thereby isolating the epi layers 222 and 226.

Thus, in this example, the trench 410 is etched after formation of the epi layers 222 and 226 (e.g., the trench 410 is etched after (i.e., post) the epi growth and/or epi deposition process). This allows the epi layers 222 and 226 to be moved closer together and even touch before the trench 410 is etched, which provides further cell height reduction. In this example, the epi layers 222 and 226 are allowed to touch during the epi growth and/or epi deposition process for further cell height reduction since the epi layers 222 and 226 are subsequently separated (i.e., isolated) by the trench 410, which cuts through the portions of the epi layers 222 and 226 that are touching.

After the etching process, the trench 410 is filled with dielectric material to form the first dielectric wall 310 shown in FIG. 3B. The dielectric material may include one or more of the following: silicon dioxide (SiO2), silicon nitride (Si3N4), silicon carbon oxynitride (SiCON), etc.

FIG. 4B shows a cross-sectional view taken along cross-section line Y3-Y4 at the same stage of chip fabrication as FIG. 4B. In this example, the etching process for the etch in the direction 405 also etches the divot 325 in the first dielectric cap 290. However, as shown in FIG. 4B, the depth of the divot 325 is smaller in the z direction than the depth of the trench 410 in the z direction due to the slower etch rate in the first dielectric cap 290. Also, as shown in FIG. 4B, the etching of the first dielectric cap 290 does not completely cut through the first dielectric cap 290, thereby protecting the underlying gate 220 from being etched. As a result, the shared gate 220 of the transistors 212 and 214 is retained. After the etching process, the divot 325 may also be filled with the same dielectric material used to form the first dielectric wall 310, as discussed further below.

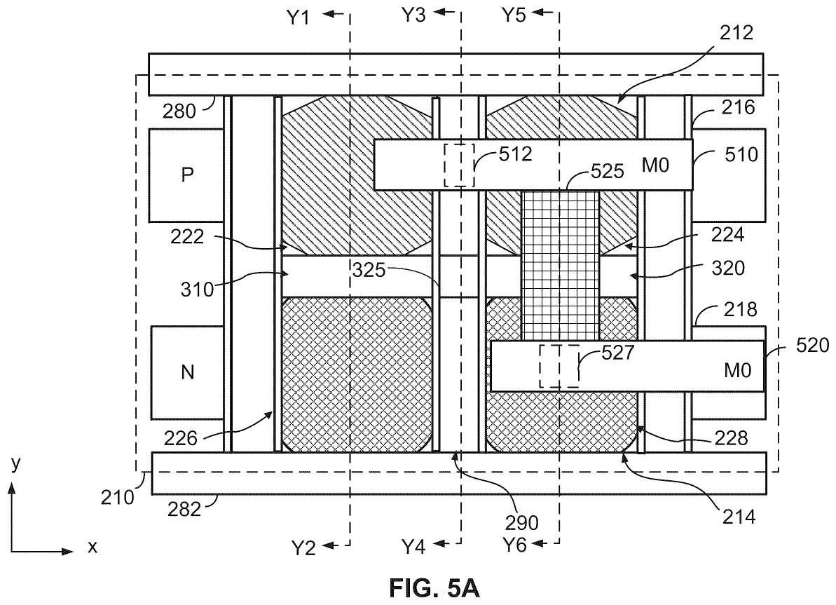

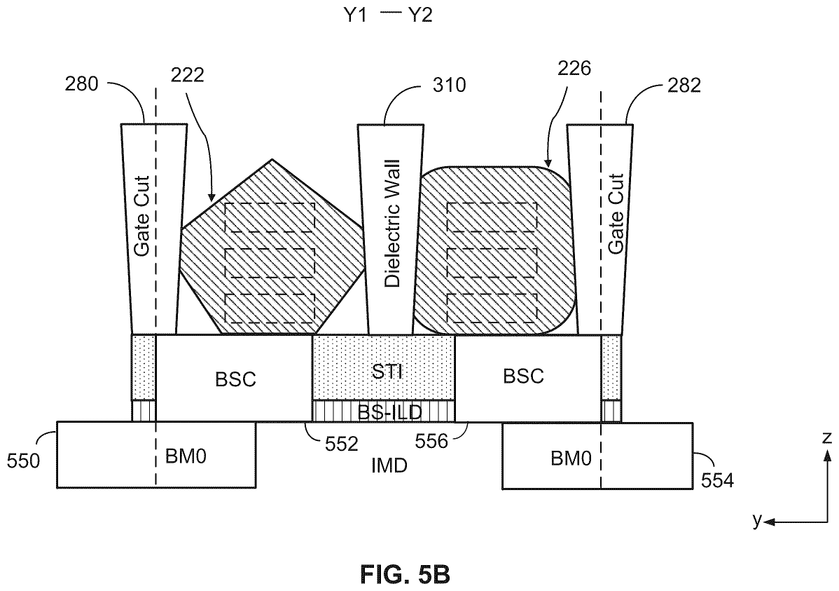

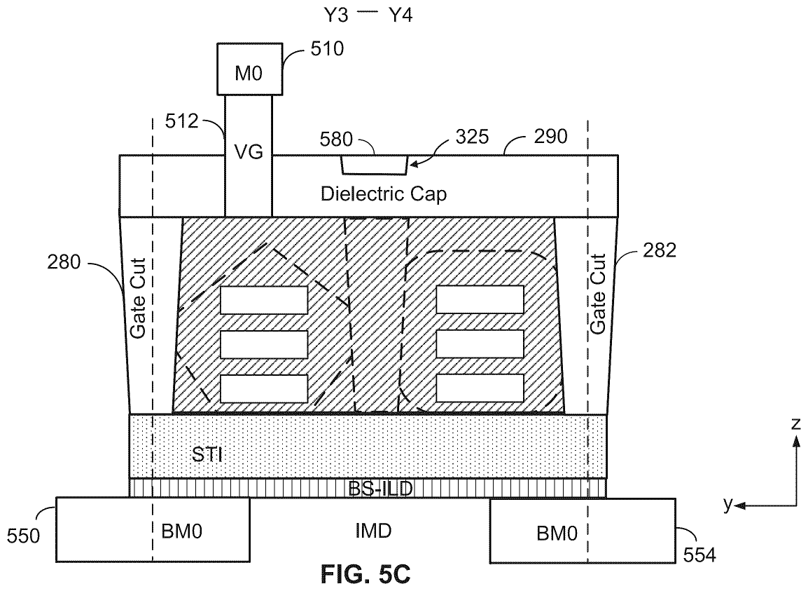

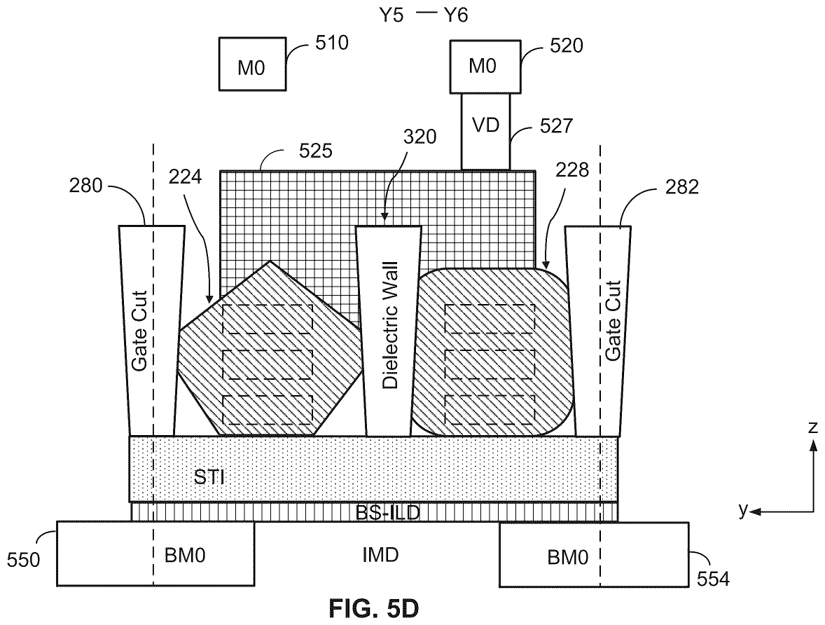

FIG. 5A shows a top view of exemplary signal routing for the cell 210 according to certain aspects. In this example, the signal routing may couple the first transistor 212 and the second transistor 214 to form a complementary inverter. However, it is to be appreciated that the present disclosure is not limited to this example.

In the example in FIG. 5A, the signal routing includes a first metal routing 510 extending in the x direction and a second metal routing 520 extending in the x direction and spaced apart from the first metal routing 510 in the y direction. The first metal routing 510 and the second metal routing 520 are both formed from metal layer M0.

The signal routing also includes a via 512 coupling the first metal routing 510 to the shared gate 220. The via 512 is disposed between the gate 220 and the first metal routing 510 in the z direction and passes through the first dielectric cap 290. In FIG. 5A, the via 512 is shown in dashed line to indicate that the via 512 is underneath the first metal routing 510. In this example, the first metal routing 510 may provide an input to the inverter.

The signal routing also includes a topside contact 525 (e.g., topside contact 124 formed from MD or CA contact layer) and a via 527 (e.g., via 134). The contact 525 extends in the y direction and is disposed on the topside of the third epi layer 224 and the topside of the fourth epi layer 228. The via 527 couples the contact 525 to the second metal routing 520 and is disposed between the contact 525 and the second metal routing 520 in the z direction. The via 527 is shown in dashed line to indicate that the via 527 is underneath the second metal routing 520. Thus, in this example, the second metal routing 520 is coupled to the third epi layer 224 and the fourth epi layer 228 through the via 527 and the contact 525. In this example, the second metal routing 520 may provide an output to the inverter.

FIG. 5B shows a cross-section view of the cell 210 taken along cross-section line Y1-Y2 in FIG. 5A. In FIG. 5B, the vertical dashed lines indicate the boundary of the cell 210. In this example, the first epi layer 222 is coupled to a first backside rail 550 by a first backside contact 552, and the second epi layer 226 is coupled to the second backside rail 554 by a second backside contact 556. The first backside rail 550 may be a supply rail coupling the first epi layer 222 to a supply voltage, and the second backside rail 554 may be a ground rail coupling the second epi layer 226 to ground. Although not shown in FIG. 5B, it is to be appreciated that backside contacts 552 and 556 may be coupled to the backside rails 550 and 554, respectively, by vias (e.g., backside via 168 in FIG. 1E). In this example, the first dielectric wall 310 isolates the first epi layer 222 from the second epi layer 226, which prevents a short between the supply voltage and ground in this example.

It is to be appreciated that aspects of the present disclosure are not limited to backside power distribution. For example, in some implementations, aspects of the present disclosure may be used in a chip that employs frontside power distribution. In this example, the first epi layer 222 may be coupled to a topside supply rail formed in metal layer M0 and the second epi layer 226 may be coupled to a topside ground rail formed in metal layer M0.

FIG. 5C shows a cross-sectional view of the cell 210 taken along cross-section line Y3-Y4 in FIG. 5A. As shown in FIG. 5C, the via 512 couples the first metal routing 510 to the gate 220 and passes through the first dielectric cap 290 to make contact with the top surface of the gate 220. FIG. 5C also shows of an example of a dielectric fill 580 in the divot 325. In this example, the dielectric material deposited in the trench 410 to form the first dielectric wall 310 may also be deposited in the divot 325 resulting in the dielectric fill 580 shown in FIG. 5C.

FIG. 5D shows a cross-sectional view of the cell 210 taken along cross-section line Y5-Y6 in FIG. 5A. As shown in FIG. 5D, the via 527 couples the second metal routing 520 to the contact 525. The contact 525 extends in the y direction and passes over the second dielectric wall 320 to couple the third epi layer 224 and the fourth epi layer 228 to the via 527.

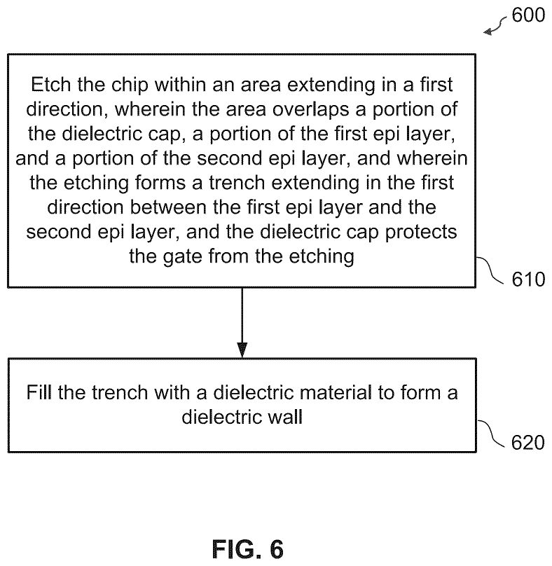

FIG. 6 shows an exemplary method 600 of chip fabrication according to certain aspects. The chip (e.g., chip 100) includes a gate (e.g., gate 220), a dielectric cap (e.g., dielectric cap 290) disposed on the gate, one or more first channels (one or more channels 270) passing through the gate, one or more second channels (one or more channels 274) passing through the gate, a first epitaxial (cpi) layer (e.g., first epi layer 222) coupled to the one or more first channels, and a second epi layer (e.g., second epi layer 226) coupled to the one or more second channels.

At block 610, the chip is etched within an area extending in a first direction, wherein the area overlaps a portion of the dielectric cap, a portion of the first epi layer, and a portion of the second epi layer, and wherein the etching forms a trench extending in the first direction between first epi layer and the second epi layer, and the dielectric cap protects the gate from the etching. For example, the area may be defined by the etch pattern 330, and the trench may correspond to the trench 410.

At block 620, the trench is filled with a dielectric material to form a dielectric wall. For example, the dielectric wall may correspond to the dielectric wall 310.

In certain aspects, the etching includes etching a divot in the dielectric cap, wherein a depth of the divot is less than a thickness of the dielectric cap. For example, the divot may correspond to the divot 325. In certain aspects, the divot 325 may also be filled with the dielectric material.

In certain aspects, the etching includes etching away the portion of the first epi layer and the portion of the second epi layer. For example, the portion of the first epi layer may touch the portion of the second epi layer. In this example, the etching isolates the first epi layer and the second epi layer by etching away the portion of the first epi layer and the portion of the second epi layer. The etching may also include etching the ILD between the first epi layer and the second epi layer.

Implementation examples are described in the following numbered clauses:
1. A chip, comprising:
   one or more first channels extending in a first direction;
   a first epitaxial (epi) layer coupled to the one or more first channels;
   one or more second channels extending in the first direction;
   a second epi layer coupled to the one or more second channels;
   a first gate extending in a second direction perpendicular to the first direction,
wherein the one or more first channels and the one or more second channels pass through the first gate;
   a first dielectric wall extending in the first direction, wherein the first dielectric wall is disposed between the first epi layer and the second epi layer; and
a dielectric cap disposed on the first gate.
2. The chip of clause 1, wherein the dielectric cap comprises silicon nitride.
3. The chip of clause 1 or 2, wherein the dielectric cap has a divot aligned with the first dielectric wall in the second direction.
4. The chip of clause 3, wherein a depth of the divot is less than a thickness of the dielectric cap.
5. The chip of clause 3 or 4, further including a dielectric fill in the divot.
6. The chip of clause 5, wherein the first dielectric wall and the dielectric fill comprise a same dielectric material.
7. The chip of any one of clauses 1 to 6, wherein the first epi layer abuts a first side of the first dielectric wall, and the second epi layer abuts a second side of the first dielectric wall.
8. The chip of any one of clauses 1 to 7, further comprising:
   a second gate extending in the second direction and aligned with the first gate in the first direction; and
   a gate cut structure disposed between the first gate and the second gate, wherein the dielectric cap is disposed on the second gate and extends over the gate cut structure in the second direction.
9. The chip of any one of clauses 1 to 8, further comprising:
   a third epi layer coupled to the one or more first channels, wherein the first gate is between the first epi layer and the third epi layer;
   a fourth epi layer coupled to the one or more second channels, wherein the first gate is between the second epi layer and the fourth epi layer; and
   a second dielectric wall extending in the first direction, wherein the second dielectric wall is disposed between the third epi layer and the fourth epi layer, and the second dielectric wall is aligned with the first dielectric wall in the second direction.
10. The chip of clause 9, wherein the dielectric cap has a divot aligned with the first dielectric wall and the second dielectric wall in the second direction.
11. The chip of clause 10, wherein a depth of the divot is less than a thickness of the dielectric cap.
12. The chip of clause 10 or 11, further including a dielectric fill in the divot.
13. The chip of clause 12, wherein the first dielectric wall, the second dielectric wall, and the dielectric fill comprise a same dielectric material.
14. The chip of any one of clauses 9 to 13, further comprising a topside contact disposed on the third epi layer and the fourth epi layer, wherein the topside contact passes over the second dielectric wall between the third epi layer and the fourth epi layer.
15. The chip of clause 14, further comprising:
   a metal routing formed from a topside metal layer; and
   a via coupling the topside contact to the metal routing.
16. The chip of any one of clauses 1 to 15, further comprising:
   a first contact coupled to the first epi layer;
   a second contact coupled to the second epi layer;
   a first rail coupled to the first contact; and
   a second rail coupled to the second contact.
17. The chip of clause 16, wherein the first rail is a supply rail and the second rail is a ground rail.
18. The chip of clause 16 or 17, wherein each of the first rail and the second rail is formed from a backside metal layer.
19. The chip of clause 16 or 17, wherein each of the first rail and the second rail is formed from a topside metal layer.
20. The chip of any one of clauses 1 to 19, further comprising:
   a metal routing formed from a topside metal layer; and
   a via coupling the first gate to the metal routing, wherein the via passes through the dielectric cap.
21. The chip of any one of clauses 1 to 20, further comprising:
   a first spacer extending in the second direction;
   a second spacer extending in the second direction, wherein the first gate is disposed between the first spacer and the second spacer, and the dielectric cap is disposed between the first spacer and the second spacer.
22. A method of chip fabrication, wherein a chip includes a gate, a dielectric cap disposed on the gate, one or more first channels passing through the gate, one or more second channels passing through the gate, a first epitaxial (epi) layer coupled to the one or more first channels, and a second epi layer coupled to the one or more second channels, the method comprising:
   etching the chip within an area extending in a first direction, wherein the area overlaps a portion of the dielectric cap, a portion of the first epi layer, and a portion of the second epi layer, and wherein the etching forms a trench extending in the first direction between first epi layer and the second epi layer, and the dielectric cap protects the gate from the etching; and
   filling the trench with a dielectric material to form a dielectric wall.
23. The method of clause 22, wherein the etching includes etching a divot in the dielectric cap, wherein a depth of the divot is less than a thickness of the dielectric cap.
24. The method of clause 23, further comprising filling the divot with the dielectric material.
25. The method of any one of clauses 22 to 24, wherein the etching includes etching away the portion of the first epi layer and the portion of the second epi layer.
26. The method of any one of clauses 22 to 25, wherein the etching includes etching away interlayer dielectric between the first epi layer and the second epi layer.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
one or more first channels extending in a first direction;
a first epitaxial (epi) layer coupled to the one or more first channels;
one or more second channels extending in the first direction;
a second epi layer coupled to the one or more second channels;
a first gate extending in a second direction perpendicular to the first direction, wherein the one or more first channels and the one or more second channels pass through the first gate;
a first dielectric wall extending in the first direction, wherein the first dielectric wall is disposed between the first epi layer and the second epi layer; and
a dielectric cap disposed on the first gate.

2. The chip of claim 1, wherein the dielectric cap comprises silicon nitride.

3. The chip of claim 1, wherein the dielectric cap has a divot aligned with the first dielectric wall in the second direction.

4. The chip of claim 3, wherein a depth of the divot is less than a thickness of the dielectric cap.

5. The chip of claim 3, further including a dielectric fill in the divot.

6. The chip of claim 5, wherein the first dielectric wall and the dielectric fill comprise a same dielectric material.

7. The chip of claim 1, wherein the first epi layer abuts a first side of the first dielectric wall, and the second epi layer abuts a second side of the first dielectric wall.

8. The chip of claim 1, further comprising:
a second gate extending in the second direction and aligned with the first gate in the first direction; and
a gate cut structure disposed between the first gate and the second gate, wherein the dielectric cap is disposed on the second gate and extends over the gate cut structure in the second direction.

9. The chip of claim 1, further comprising:
a third epi layer coupled to the one or more first channels, wherein the first gate is between the first epi layer and the third epi layer;
a fourth epi layer coupled to the one or more second channels, wherein the first gate is between the second epi layer and the fourth epi layer; and
a second dielectric wall extending in the first direction, wherein the second dielectric wall is disposed between the third epi layer and the fourth epi layer, and the second dielectric wall is aligned with the first dielectric wall in the second direction.

10. The chip of claim 9, wherein the dielectric cap has a divot aligned with the first dielectric wall and the second dielectric wall in the second direction.

11. The chip of claim 10, wherein a depth of the divot is less than a thickness of the dielectric cap.

12. The chip of claim 10, further including a dielectric fill in the divot.

13. The chip of claim 12, wherein the first dielectric wall, the second dielectric wall, and the dielectric fill comprise a same dielectric material.

14. The chip of claim 9, further comprising a topside contact disposed on the third epi layer and the fourth epi layer, wherein the topside contact passes over the second dielectric wall between the third epi layer and the fourth epi layer.

15. The chip of claim 14, further comprising:
a metal routing formed from a topside metal layer; and
a via coupling the topside contact to the metal routing.

16. The chip of claim 1, further comprising:
a first contact coupled to the first epi layer;
a second contact coupled to the second epi layer;
a first rail coupled to the first contact; and
a second rail coupled to the second contact.

17. A method of chip fabrication, wherein a chip includes a gate, a dielectric cap disposed on the gate, one or more first channels passing through the gate, one or more second channels passing through the gate, a first epitaxial (epi) layer coupled to the one or more first channels, and a second epi layer coupled to the one or more second channels, the method comprising:
etching the chip within an area extending in a first direction, wherein the area overlaps a portion of the dielectric cap, a portion of the first epi layer, and a portion of the second epi layer, and wherein the etching forms a trench extending in the first direction between first epi layer and the second epi layer, and the dielectric cap protects the gate from the etching; and
filling the trench with a dielectric material to form a dielectric wall.

18. The method of claim 17, wherein the etching includes etching a divot in the dielectric cap, wherein a depth of the divot is less than a thickness of the dielectric cap.

19. The method of claim 18, further comprising filling the divot with the dielectric material.

20. The method of claim 17, wherein the etching includes etching away the portion of the first epi layer and the portion of the second epi layer.
